(19) United States
(12) Patent Application Publication
(10) Pub. No.: US 2014/0111220 A1
(43) Pub. Date: Apr. 24, 2014

(54) METHOD FOR FAULT DIAGNOSIS ON SOLAR MODULES

(71) Applicant: Anders Rand Andersen, Odense M (DK)

(72) Inventor: Anders Rand Andersen, Odense M (DK)

(73) Assignee: EMAZYS TECHNOLOGIES APS, Odense M (DK)

(21) Appl. No.: 14/116,551

(22) PCT Filed: May 8, 2012
(86) PCT No.: PCT/DK2012/050154

§ 371 Date: Dec. 30, 2013

(30) Foreign Application Priority Data
May 11, 2011 (DK) PA 2011 00366
Jun. 17, 2011 (DK) PA 2011 00459

(51) Int. Cl. G01R 31/26

(52) U.S. Cl. CPC G01R 31/2605
USPC 324/534; 324/761.01

(57) ABSTRACT

There is provided a method for fault diagnosis on a solar module in which electrical potentials are checked within the solar module to provide the possibility for carrying out the fault diagnosis even when the solar module is not exposed to sun light. Specifically the solar cell module is excited by both a DCBIAS and an AC voltage over a wide frequency range, and the impedance of the solar cell module is measured as a function of the frequency response. There is also provided an embodiment, wherein time domain reflectometry (TDR) is used in combination with the DC BIAS and AC voltage based fault diagnosis. Based on the method safety operations can be carried out as a part of the integrated electric functionality.

### FIELD OF THE INVENTION

The present invention relates to a method for fault diagnosis on a solar module in which electric parameters are measured within the solar module and in the materials constituting a solar power system (wires, soldering etc.) to provide the possibility for carrying out the fault diagnosis even when the solar module is not exposed to sun light. Specifically solar cell modules are excited by both a DC BIAS and an AC voltage over a wide frequency range, and the impedance of the modules is measured as a function of the frequency response and the DC BIAS.

### BACKGROUND OF THE INVENTION

Determining the characteristics of the performance of solar cells is essential to improve their optimization for sunlight energy conversion. Impedance spectroscopy (IS) is a tool in many areas of materials science and electrical device technology, and it has been applied to small area silicon solar cells as well as other solar cell types, in research laboratories.

The analysis of experimental results shows that in Si solar cells it is possible to separate the physical components of the capacitance, as well as to monitor the variation of the different internal resistances over different levels of illumination.

The IS technique is based on analysing the electrical response of a material, to an oscillating electromagnetic (EM) field. The EM field is applied as an alternating current (AC) or voltage at two electrical terminals in contact with the material. Typically one is interested in analysing the impedance in a wide frequency range. IS is widely applied in a broad class of materials systems and devices, including inorganic, organic and biological systems. In solar cell science and technology the most commonly applied frequency technique is admittance spectroscopy.

It should be remarked that impedance and admittance are reciprocal functions, so that they give exactly the same information. However, by tradition admittance spectroscopy denominates a special method that operates at reverse voltage and evaluates the energy levels of the majority of carrier traps (in general, all those that cross the Fermi level) as well as trap densities of states.

In contrast to this, in electrochemistry one is usually more interested in injecting electronic charge into the electrode, and the term generally adopted is electrochemical impedance spectroscopy (EIS). In solar cells it is clearly important to perform frequency analysis in the reverse region of the diode characteristics, since this probes the selectivity of the contacts. By exploring the forward bias range, both in dark and under illumination with different light intensities, a variety of properties can be separately investigated, including transport in the photoactive layer, contacts, bulk and surface capacitance, etc. This approach has been amply used in recent years for dye-sensitized solar cells (DSC) and organic solar cells, while there are only a few works to date on solid state devices, such as those based on nanocrystalline/amorphous Si, thin-film, CdTe/CdS, GaAs/Ge, and CdS/Cu(In,Ga)Se2 solar cells (Energy Environ. Sci., 2009, 2, 678-686).

TDR is often used to diagnose conventional transmission lines (mostly coaxial lines). This method consist of transmitting an electrical signal (usually a voltage pulse or voltage step) in a transmission line, and analyze the reflections that occur along the line. Indeed, if the signal experiences a fault on the line, a part of the signal will be reflected to the line input. Usually, these reflections are measured using an echometer. An echometer is a device that generates electrical pulses and fitted with a screen showing the different reflections occurring.

To apply TDR to photovoltaic modules and strings of modules, a corresponding model for each component of this line should be defined. In the field of photovoltaics, single conductor cables are commonly used, whereas in the case of transmission lines on which time domain reflectometry is generally applied (coaxial cables, parallel wire lines, etc.) which are composed of two conductors.

It should be noted that TDR raises some difficulties in relation to photovoltaic modules strings. Issues related to methods of installation of plants on site (problems of parallelism between photovoltaic cables and the ground, etc.) and the multiple reflections occurring on a string make it difficult to interpret the results that could provide TDR. There is also a lack of sensitivity of the method: As the equivalent impedances of different parts of the string (cable and modules) are very high, it is almost impossible to detect a fault in the string, which would result in practice in a very low impedance variation. However when using a DC BIAS the impedance in the solar modules is lowered dramatically and hence the sensitivity achieved by the invention, i.e. the combined TDR apparatus and the DC potentiostat, allows for useful measurements.

WO 2011/032993 A1 describes a method for characterising at least one solar cell module and monitoring changes over time, including changes attributable to faults. The method comprises applying an AC voltage with an amplitude of 10 V to 2 kV to the solar cells in a broad frequency range from 1 kHz to 2 MHz, and measuring the impedance as a function of the frequency. Changes in the impedance spectrum with respect to earlier recorded impedance spectra are detected. Computing means calculates measuring values from the detected changes, and measuring results from different points in time are stored. WO 2011/032993 A1 does not envisage the use of a DC bias and evaluate the measurements in terms of fitting a physical model to the measured data. The present invention provides a method for the detection of material-specific changes in interconnected solar modules that temporally evolves in the processed materials of the modules and their interconnections, effected by outside and inner causes, before the occurrence of larger damages are recognizable. This is not possible with the system in WO 2011/032993 A1, wherein even small variations in daylight that would otherwise seem invisible to the eye, are captured by the string of solar cells resulting in a continuous variation in photo-voltage. The present invention constitutes an improvement over WO 2011/032993 A1, wherein the reliability of the fault diagnosis in solar cell systems having multiple solar cell modules is improved.

It is an object of the present invention to provide a more reliable method for fault diagnosis of solar cell modules.

### SUMMARY OF THE INVENTION

Specifically, in one aspect the present invention provides a method for diagnosing failure modes within a solar cell system including one or more solar cell modules, said method comprising the steps:
i) applying with a power potentiostat a constant electric potential or current in the form of a DC signal across/through the solar cell modules, said potential being in the range of −1000 to +1000 Volts DC (potentiostatic mode) or a DC current typically in the range of 5-10 Amperes (galvanostatic mode);
ii) applying in addition to the DC BIAS of i) an AC voltage, while scanning a frequency range from 1 Hz to 10 MHz to achieve an impedance spectrum;
iii) comparing the impedance spectrum with a control impedance spectrum recorded from an intact solar cell system or a previously measured impedance spectrum on a subunit of the entire solar power system; and
iv) diagnosing faults by detection of significant changes in model parameters, when numerically fitting a physical model to measured electrical data.

In another aspect of the present invention there is provided system for diagnosing a fault within solar cell system including multiple solar cell modules, said system comprising:
i) a power potentiostat for applying an electric BIAS in the form of a DC signal over the solar cell modules;
ii) an AC source for applying in addition to the DC voltage of i) an AC voltage, said AC source capable of scanning a frequency range from 1 Hz to 10MHz with a an AC amplitude up to 1000 Volts AC thereby generating an impedance spectrum;
iii) means for comparing the impedance spectrum with a control impedance spectrum recorded from an intact solar cell system or recorded previously at the solar system in where the invention is installed; and
iv) means for diagnosing faults according to the following scheme: automatically transferring the measured data to a central data base where a control computer fitting a physical model to the data and store the parameters deduced from this modelling routine.

The present invention in a particularly preferred embodiment includes the use of time domain reflectometry (TDR) to specifically identify the type and physical position of a failure mode; a failure mode that is either present at installation, slowly developing or abruptly induced.

When time domain reflectometry (TDR) is used in combination with the DC BIAS and AC voltage based fault diagnosis a particularly useful method and system for diagnosing failure modes within a solar cell system is achieved. Thereby not only the type of failure is identified but also the physical position for the failure is determined. The physical position is understood as the subsystem in the electrical circuit of solar cell modules and components. Typically the system is a string of 7-10 modules in a series connection, and hence the failure mode will be identified in a single or a specific plural of modules in the string or its connections.

A remarkable feature with respect to the impedance spectrum of semiconductor solar cells is that it depends totally on the operating point (I,V). Especially the impedance varies drastically at operating points in the vicinity of the maximum power point (V_{MPP}, I_{MPP}). A potentiostat thus allows that impedance data can be measured at different operating points, which makes detailed analysis involving large series of different spectra possible. It furthermore ensures that measurements can be done at similar conditions from day to day. The latter is essential for comparison of different spectra obtained during the life cycle of a PV installation.

The procedure for data analysis is to import the measured impedance data as a function of frequency, BIAS and temperature Z(f, V, T) and use the data either in the form (phase angle, total impedance, frequency)=(∥Z∥, θf) or to convert the data format: (real part, imaginary part, frequency)=(Zᵣₑₐₗ, Z_{imag}, f). A data point in this set is then typically considered as a vector in the complex plane. The impedance is thus characterized as a function of specific physical parameters Pᵢ as well as the actual age, t_{PV} of the solar cell installation, so the impedance function is noted as Z(Pᵢ,t_{PV})

By using a physical model, which could be an equivalent circuit model containing the solar cell parameters, and by for instance employing a “complex nonlinear least square” CNLS mathematical method for fitting the model to the data, the result will be a list of parameters. The model is a mathematical function, and this function (equation) is deduced when the applied equivalent circuit is analysed. Complex solar module connections will have a complex equivalent circuit and less complex systems, e.g. simple strings of modules, will have a less complex equivalent circuit. The specific model used for analysis is therefore tailored to the specific system, or group of systems. The result of the automated fitting procedure is stored and used for comparison when a new spectrum is recorded at a later time.

The physical model will depend on the system, but typically equivalent circuit models based on transmission lines will be employed for analysis of impedance spectra. The result of the automated fitting procedure is stored and used for comparison when a new spectrum is recorded at a later time.

The impedance spectrum and hence the model parameters that can be deduced, will have a characteristic frequency and a strong DC potential dependence. Normally features in the impedance spectrum arising from leeds, wires, soldering, and other metallic (ohmic) materials will show at the highest frequencies while features arising from the semiconductor materials in the solar cells will show at medium frequencies. It is essential that impedance features (observed as curve/peak shapes in either a Nyquist or a Bode type plot) will depend heavily on DC potential, illumination and temperature, and comparison of data is therefore based data obtained under the same physical conditions. While the aim is to characterize the solar installation at different times, t_{PV}, throughout the entire lifetime and search for faults.

The present invention provides a method for the detection of material-specific changes in interconnected solar modules that temporally evolves in the processed materials of the modules and their interconnections, effected by outside and inner causes, before the occurrence of larger damages are recognizable.

Also a regular quality control of the produced modules and their installation in a solar generator must be possible. A group of interconnected solar cell modules are subjected to both DC and AC voltage over a great frequency range and the impedance is recorded as a function of the frequency response measured. These measurements can be repeated at even intervals. From one measurement to the next the change of the measurement data is an indication for changes in the used materials or interconnection of the solar generator. The DC power potentiostat may also serve to keep the energy yield high by boosting the voltage of a number of solar cells.

In response of the inner and outside inductances, capacitances and resistances the ageing condition produce a characteristic frequency response of the impedance (impedance spectrum), for a given design of the devices. These outside and inner influences are e.g. the UV irradiation, temperature, temperature changes, the concentration of humidity and duration thereof.

In particular according to the present invention the course of the impedance as function of an AC and DC BIAS in series or parallel,
applied between the positive and the negative pole on a module,
or modules interconnected in matrix and/or interconnected module strings in direct contact
or at the DC voltage side of corresponding inverters in a far frequency range measured.

In particular are also provided that the impedance for the characterization of resultant changes and for the early recognition of malfunctions such as corrosion, contact problems, and de-lamination, all of which decrease the efficiency and potentially the lifetime of the entire system. Specifically the method allows to distinguish between performance degradation that stems from interior faults suchs as described above or external faults caused by shading, dirt etc.

The system consisting (the invention) of a central database and measurement device (C and B in FIG. 1) may be installed in existing systems before or after the DC to AC power inverter.

### BRIEF DESCRIPTION OF THE DRAWINGS

FIG. 1 shows the system for analysis in a schematic form.

FIG. 2 shows the device that is used to characterise a series of solar units.

### DETAILED DESCRIPTION OF THE INVENTION

In the following the present invention is described in more detail.

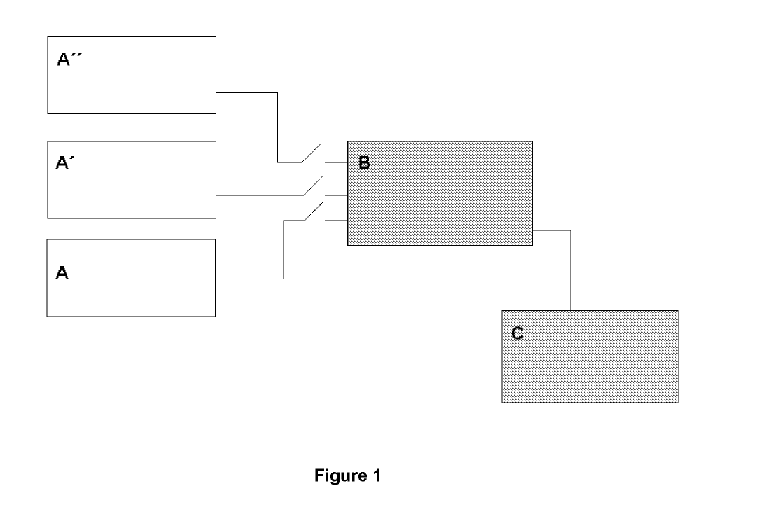

Referring to FIG. 1 there is shown the system for analysis in a schematic form. A, A′ and A″ is a sequence of subunits of a larger photovoltaic power system (typically A will be a so called string consisting of typically 7-10 modules), B is the characterization device containing a DC potentiostat capable of operating both in potentiostatic or galvanostatic mode, an AC frequency generator, a frequency response analyser (FRA) and a computer with network access to other computers in the system, C is a central database (CDB) that can store and analyse data. The units A, B and C are meant to automatically interact based on a computer control carried out in CDB computer system. Connections between A and B (including switches) shows that one B device may characterise a series of subunits by using a switch.

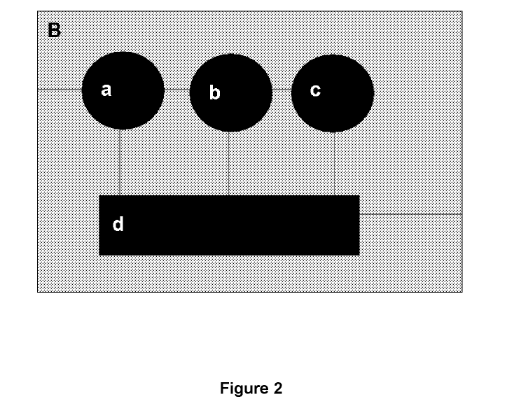

FIG. 2 shows the main characterization device which consist of a) a DC power potentiostat, b) an AC frequency generator, c) a frequency response analyser and d) an integrated control computer that can control the measurement, store data and communicate with mainly central data base (see FIG. 1).

The method of the present invention preferably involves the following aspects:
1) Scanning routine at a certain electric potential set either by the power potentiostat or by illumination, on a subunit of the the solar power system (typically a string) which is an electrically isolated subunit of the whole photovoltaic system.
2) The result from the scanning routine is converted to a suitable data format and transmitted to the CDB for further analysis.
3) The instruction to perform a scan can be a part of a planned routine or it can be based on the event where the analysis procedure identifies a significant difference between collected data sets. The latter will automatically initiate further data collection, in depth analysis and potentially and alarm will be generated.
4) Instructions from the CDB to perform a scan or initiate some other action (an action that preserves high energy yields or protects the system) is based on previously collected data as well as special control algorithms installed on the CDB main computer.
5) The measurement device (B in FIG. 1) will help right after installation of solar modules, in finding subunits that does not perform as expected and help to clarify what needs to be done in order to restore the photovoltaic power plant.
6) After some period of time there will typically occur descent in performance which is either slowly induced by ageing effects or more rapidly occurring after for instance thunder storms or theft of modules. The method plays an essential role in detecting slowly induced changes as well as measuring the effect of more abrupt phenomenon.
7) Slowly induced material degradation and performance loss, is treated based on certain algorithms that will identify problematic areas and help to rationalize maintenance.
8) A user friendly system interface, intended for service and maintenance is an integral part of the invention.
9) Abrupt changes at the power plant will be translated into alarm messages, and a work plan for restoring energy production will be generated.
10) The system (invention) is able to monitor and evaluate photovoltaic power systems, and hence the system is furthermore intended as a financial forecasting tool that can be used for evaluating new types of solar cells with unknown life cycles.

### Time Domain Reflectometry (TDR) to Specifically Identify the Type and Physical Position of a Fault

According to the present invention the TDR method is used to further characterise the failure mode and hence act as a supplement to the impedance method.

The signal reflection profile depends on the impedance in the transmission line and therefore the TDR measurement is sensitive to the BIAS settings on the DC potentiostat. The TDR measurement can be carried out at any BIAS set by the DC potentiostat.

The TDR measurement hardware is be based on extensions of the main impedance measurement hardware. This means that the frequency generator is constructed so that it can deliver continuous AC voltage or current in a wide frequency interval as well as voltage or current pulses. The pulse rise time (duration) is in the range below nanosecond to 1 ms. The amplitude of the pulse is in the range from microvolts to about 100 V.

The detection of the reflected pulse is based on an extended frequency response analyzer (FRA) device. The actual measurement of the initial pulse and the reflected pulse is a time based measurement where either the voltage or current is detected as a function time.

Data is recorded and stored in the FRA, and subsequently transferred to the central database. TDR data is thus recorded and stored on a daily basis. Any deviation in signal reflection profile can hence be detected by comparing two or more measurements.

The hardware governing the invention must be connected to the two electrical terminals of some connection of solar modules. The realisation involves that the invention is either considered as a stand-alone system or as an integrated part of the DC to AC inverter. The entire fault detection system may be installed in different types of inverters such as string inverters, central inverters, micro inverters and parallel inverters.

The hardware used according to this embodiment of the invention comprises a DC potentiostat, a frequency generator, and a frequency response analyser (FRA). These hardware parts may also serve other purposes if integrated in the inverter.

The DC potentiostat can be used as an electronic load for keeping energy yields as high as possible. Especially the potentiostat is able to keep the assembly of connected solar modules at the maximum power point (MPP) thereby ensuring maximum yield by keeping the product of photovoltage and photocurrent optimized for maximum power extraction. If a failure mode is identified by the system it is in some cases relevant to draw less current in the solar module system to minimize heating effects, and in this case the DC potentiostat is used specifically for keeping the system at the maximum allowed power point.

A well known and dangerous failure mode is the occurrence of light arcs between the conducting parts of the module and components. Light arcs are static ion channels that will establish transport of sufficiently high electrical currents, i.e. charge transport takes place through a plasma. The plasma is very hot and naturally all combustible materials in the vicinity of the arc will catch on fire and burn. The light arc is observed as a dramatic change in system impedance and hence it can be identified. The invention discloses the automatic detection of light arcs by the impedance method or by the TDR method, and the disruption of DC current via the inverter, short circuiting via the inverter or setting up a DC current with the potentiostat that exactly opposes and cancels out the current causing the light arc.

1. Method for diagnosing a fault within solar cell system comprising multiple solar cell modules, said method comprising the steps carried out any time in the day potentially also in the dark:
i) applying with a power potentiostat an electric BIAS in the form of a DC signal over the solar cell modules, being in the range of −1000 to +1000 Volts DC in the potentiostatic mode, or 5-10 Amperes in the galvanostatic mode;
ii) applying in addition to the DC voltage of i) an AC voltage, while scanning a frequency range from 1 Hz to 10MHz with a an AC amplitude up to 1000 Volts AC;
iii) comparing the impedance spectrum with a control impedance spectrum recorded from an intact solar cell system or recorded previously at the solar system in where the invention is installed; and
iv) diagnosing faults according to the following scheme:
automatically transferring the measured data to a central data base where a control computer fitting a physical model to the data and store the parameters deduced from this modelling routine.

2. Method according to claim 1, wherein the method further comprises the use of time domain reflectometry (TDR) to specifically identify the type and physical position of a fault.

3. Method according to claim 1, wherein deviations in recorded spectra in the frequency range 1 Hz-10 MHz are detected automatically by a computer program and used for further analysis of the system.

4. Method according to claim 1, wherein the physical model is based on an equivalent solar cell circuit, containing circuit elements relevant for the system that has been characterized.

5. System for diagnosing a fault within solar cell system comprising multiple solar cell modules, said system comprising:
i) a power potentiostat for applying an electric BIAS in the form of a DC signal over the solar cell modules;
ii) an AC source for applying in addition to the DC voltage of i) an AC voltage, said AC source capable of scanning a frequency range from 1 Hz to 10MHz with a an AC amplitude up to 1000 Volts AC thereby generating an impedance spectrum;
iii) means for comparing the impedance spectrum with a control impedance spectrum recorded from an intact solar cell system or recorded previously at the solar system in where the invention is installed; and
iv) means for diagnosing faults according to the following scheme:
automatically transferring the measured data to a central data base where a control computer fitting a physical model to the data and store the parameters deduced from this modelling routine.

6. System according to claim 5, wherein the system further comprises a time domain reflectometry (TDR) apparatus to specifically identify the type and physical position of a fault.
